(19) United States
(12) Patent Application Publication
(10) Pub. No.: US 2008/0012471 A1
(43) Pub. Date: Jan. 17, 2008

(54) OLED DEVICE HAVING IMPROVED LIGHT OUTPUT

(75) Inventor: Ronald S. Cok, Rochester, NY (US)

Correspondence Address: EASTMAN KODAK COMPANY;PATENT LEGAL STAFF, 343 STATE STREET, ROCHESTER, NY, 14650-2201, US

(73) Assignee: Eastman Kodak Company

(21) Appl. No.: 11/427,603

(22) Filed: Jun. 29, 2006

(51) Int. Cl. H01L 51/50; H05B 33/14

(52) U.S. Cl. 313/503; 313/501; 313/504

(57) ABSTRACT

An organic light-emitting diode (OLED) device, comprising: a transparent substrate; a transparent thin-film transistor located over the substrate; a light-emitting element formed over the transparent thin-film transistor, wherein the light-emitting element comprises a first transparent extensive electrode formed at least partially over a portion of the transparent thin-film transistor, a layer of light-emitting organic material, and a second reflective electrode formed over the layer of light-emitting organic material; a low-index layer formed between the first transparent extensive electrode and the thin-film transistor; and a light-scattering layer formed between the low-index layer and the second reflective electrode, or formed as part of the second reflective electrode.

### FIELD OF THE INVENTION

The present invention relates to organic light-emitting diode (OLED) devices, and more particularly, to OLED device structures for improving light output and device lifetime.

### BACKGROUND OF THE INVENTION

Organic light-emitting diodes (OLEDs) are a promising technology for flat-panel displays and area illumination lamps. The technology relies upon thin-film layers of materials coated upon a substrate. OLED devices generally can have two formats known as small-molecule devices such as disclosed in U.S. Pat. No. 4,476,292 and polymer-OLED devices such as disclosed in U.S. Pat. No. 5,247,190. Either type of OLED device may include, in sequence, an anode, an organic EL element, and a cathode. The organic EL element disposed between the anode and the cathode commonly includes an organic hole-transporting layer (HTL), a light-emissive layer (LEL) and an organic electron-transporting layer (ETL). Holes and electrons recombine and emit light in the LEL layer. Tang et al. (Appl. Phys. Lett., 51, 913 (1987), Journal of Applied Physics, 65, 3610 (1989), and U.S. Pat. No. 4,769,292) demonstrated highly efficient OLEDs using such a layer structure. Since then, numerous OLEDs with alternative layer structures, including polymeric materials, have been disclosed and device performance has been improved.

Light is generated in an OLED device when electrons and holes that are injected from the cathode and anode, respectively, flow through the electron transport layer and the hole transport layer and recombine in the emissive layer. Many factors determine the efficiency of this light-generating process. For example, the selection of anode and cathode materials can determine how efficiently the electrons and holes are injected into the device; the selection of ETL and HTL can determine how efficiently the electrons and holes are transported in the device, and the selection of LEL can determine how efficiently the electrons and holes are recombined and result in the emission of light, etc.

A typical OLED device uses a glass substrate, a transparent conducting anode such as indium-tin-oxide (ITO), a stack of organic layers, and a reflective cathode layer. Light generated from the device is emitted through the glass substrate, and this is commonly referred to as a bottom-emitting device. Alternatively, an OLED device can include a substrate, a reflective anode, a stack of organic layers, and a top transparent cathode layer. Light generated from this alternative device is emitted through the top transparent electrode, and this is commonly referred to as a top-emitting device. In general, bottom-emitting OLED devices are easier to manufacture because the transparent electrode (e.g. ITO) employed in a top-emitting device is difficult to deposit over the organic layers without damaging them and suffers from limited conductivity. In contrast, the evaporation of a reflective metal electrode over the organic layers has proved to be relatively robust and conductive. However, active-matrix bottom-emitting OLED devices suffer from a reduced light-emitting area (aperture ratio), since a significant proportion (over 70%) of the substrate area can be taken up by the active-matrix components, bus lines, etc. Since OLED materials degrade in proportion to the current density passed through them, a reduced aperture ratio will increase the current density through the organic layers at a constant brightness, thereby significantly reducing the OLED device lifetime. Top-emitting OLED devices can employ an increased aperture ratio, since light emitted from the device passes through the cover rather than the substrate. Active-matrix devices formed on the substrate can be covered with an insulating layer and a reflective electrode formed over the active-matrix components, thereby increasing the light-emitting area. Active-matrix components, typically thin-film transistors are formed on the substrate using photolithographic processes. Such processes cannot be performed over organic layers, since the processes will destroy the organic layers and any OLED formed under them.

Displays that emit light from both sides of the device are also known. US20060038752 A1, for example, describes an emissive display device for producing images that has a plurality of first pixels each having an emissive area wherein the plurality of first pixels define a first viewing region, wherein each first pixel produces light emission which is visible when viewing the first side of the display device; and a plurality of second pixels each having an emissive area and wherein the plurality of second pixels define a second viewing region, wherein each second pixel produces light emission which is visible when viewing the second side of the display device, wherein at least a portion of the plurality of first and second pixels are interleaved.

Transparent inorganic and organic materials from which thin-film transistors can be made are also known. For example inorganic doped metal oxides such as aluminum zinc oxide can be employed as well as organic materials such as pentacene. Using these materials, completely transparent displays may be constructed. For example, in “Towards see-through displays: fully transparent thin-film transistors driving transparent organic light-emitting diodes,” in Advanced Materials, 2006, 18(6), 738-741 published by Wiley-VCH Verlag GmbH & Co., entirely transparent pixels composed of monolithically integrated transparent organic light-emitting diodes driven by transparent thin-film transistors are presented. With an average transmittance of more than 70% in the visible part of the spectrum (400-750 nm), the presented active pixels may enable the realization of practically transparent active-matrix displays. However, in many applications a transparent display is not desired while an improved display emitting light from one side is desired.

US2004/0155846 entitled “Transparent Active-Matrix Display” describes the use of transparent active pixel elements and transparent electrical connections. While the disclosure is primarily directed towards use of such transparent pixel elements in display devices that emit light from both sides of the device, it is disclosed that transparent thin-film transistors may be employed with a transparent bottom electrode together with a reflective back (top) electrode formed over the otherwise transparent pixel elements. Such embodiment may provide a greater aperture ratio in a bottom-emitter OLED device, compared to bottom-emitting devices employing conventional non-transparent thin-film transistors. Referring to FIG. 2, a bottom-emitting active-matrix OLED as may be suggested by the prior-art has a transparent substrate 10, a layer of transparent thin-film electronic components 30 formed over the substrate 10. Planarization insulating layer 32 protects the layer of thin-film electronic components 30. A transparent electrode 12 is formed over the substrate 10, planarization insulating layer 32, and at least partially over the layer of thin-film electronic components 30. A second planarization insulating layer 34 is formed between the transparent electrodes 12 to prevent shorts between them. One or more layers 14 of organic material, one of which is light-emitting, is formed over the transparent electrodes 12 and a common, reflective electrode 16 is formed over the layers 14 of organic material. To simplify the manufacturing process, the organic layers 14 and reflective electrode 16 are typically formed over the entire device, even though only those portions 60 of the device corresponding to the extent of the transparent electrode 12 will emit light 64. The transparent electrodes 12 may be formed adjacent to and over the active-matrix components 30 because the components 30 are transparent and light 64 emitted from the portion 60 can pass through the active-matrix components 30 and out of the OLED device. Because the electrodes 12 and 16 extend over the transparent active-matrix thin-film electronic components 30, the portions 60 of the OLED device that emits light 64 may be much larger than if the active-matrix components 30 were not transparent, thereby improving the lifetime of the OLED device. An encapsulating cover 20 may be located over the transparent electrode 12 and adhered to the substrate 10 to protect the OLED device.

Typical indices of refraction for the organic layers range from 1.6 to 1.7 and the refractive index of commonly used transparent conductive metal oxides such as indium tin oxide (ITO) is often greater than 1.8 and often near 2.0. Hence, light emitted in an organic layer at a high angle with respect to the normal can totally internally reflect and be trapped in the high optical index materials of the organic layers and transparent electrodes, and not be emitted from the device, thereby reducing the efficiency of the OLED device. Hence, light may be trapped in the high-index layers 10, 30, 12, 14, 32, and 34.

A variety of techniques have been proposed to improve the out-coupling of light from thin-film, light-emitting devices. For example, diffraction gratings have been proposed to control the attributes of light emission from thin polymer films by inducing Bragg scattering of light that is guided laterally through the emissive layers; see “Modification of polymer light emission by lateral microstructure” by Safonov et al., Synthetic Metals 116, 2001, pp. 145-148, and “Bragg scattering from periodically microstructured light emitting diodes” by Lupton et al., Applied Physics Letters, Vol. 77, No. 21, Nov. 20, 2000, pp. 3340-3342. Brightness enhancement films having diffractive properties and surface and volume diffusers are described in WO0237568 A1 entitled “Brightness and Contrast Enhancement of Direct View Emissive Displays” by Chou et al., published May 10, 2002. The use of micro-cavity techniques is also known; for example, see “Sharply directed emission in organic electroluminescent diodes with an optical-microcavity structure” by Tsutsui et al., Applied Physics Letters 65, No. 15, Oct. 10, 1994, pp. 1868-1870. However, none of these approaches cause all, or nearly all, of the light produced to be emitted from the device. Moreover, such diffractive techniques cause a significant frequency dependence on the angle of emission so that the color of the light emitted from the device changes with the viewer's perspective.

Reflective structures surrounding a light-emitting area or pixel are referenced in U.S. Pat. No. 5,834,893 issued Nov. 10, 1998 to Bulovic et al. and describe the use of angled or slanted reflective walls at the edge of each pixel. Similarly, Forrest et al. describe pixels with slanted walls in U.S. Pat. No. 6,091,195 issued Jul. 18, 2000. These approaches use reflectors located at the edges of the light-emitting areas. However, considerable light is still lost through absorption of the light as it travels laterally through the layers parallel to the substrate within a single pixel or light emitting area.

Scattering techniques are also known. Chou (International Publication Number WO 02/37580 A1) and Liu et al. (U.S. Patent Application Publication No. 2001/0026124 A1) taught the use of a volume or surface scattering layer to improve light extraction. The scattering layer is applied next to the organic layers or on the outside surface of the glass substrate and has an optical index that matches these layers. Light emitted from the OLED device at higher than critical angle that would have otherwise been trapped can penetrate into the scattering layer and be scattered out of the device. The efficiency of the OLED device is thereby improved but still has deficiencies as explained below.

U.S. Pat. No. 6,787,796 entitled “Organic electroluminescent display device and method of manufacturing the same” by Do et al issued 20040907 describes an organic electroluminescent (EL) display device and a method of manufacturing the same. The organic EL device includes a substrate layer, a first electrode layer formed on the substrate layer, an organic layer formed on the first electrode layer, and a second electrode layer formed on the organic layer, wherein a light loss preventing layer having different refractive index areas is formed between layers of the organic EL device having a large difference in refractive index among the respective layers. U.S. Patent Application Publication No. 2004/0217702 entitled “Light extracting designs for organic light emitting diodes” by Garner et al., similarly discloses use of microstructures to provide internal refractive index variations or internal or surface physical variations that function to perturb the propagation of internal waveguide modes within an OLED. When employed in a top-emitter embodiment, the use of an index-matched polymer adjacent the encapsulating cover is disclosed. US20050142379 A1 entitled “Electroluminescence device, planar light source and display using the same” describes an organic electroluminescence device including an organic layer comprising an emissive layer; a pair of electrodes comprising an anode and a cathode, and sandwiching the organic layer, wherein at least one of the electrodes is transparent; a transparent layer provided adjacent to a light extracting surface of the transparent electrode; and a region substantially disturbing reflection and retraction angle of light provided adjacent to a light extracting surface of the transparent layer or in an interior of the transparent layer, wherein the transparent layer has a refractive index substantially equal to or more than the refractive index of the emissive layer.

Light-scattering layers used externally to an OLED device are described in U.S. Patent Application Publication No. 2005/0018431 entitled “Organic electroluminescent devices having improved light extraction” by Shiang and U.S. Pat. No. 5,955,837 entitled “System with an active layer of a medium having light-scattering properties for flat-panel display devices” by Horikx, et al. These disclosures describe and define properties of scattering layers located on a substrate in detail. Likewise, U.S. Pat. No. 6,777,871 entitled “Organic ElectroLuminescent Devices with Enhanced Light Extraction” by Duggal et al., describes the use of an output coupler comprising a composite layer having specific refractive indices and scattering properties. While useful for extracting light, this approach will only extract light that propagates in the substrate, and will not extract light that propagates through the organic layers and electrodes. Moreover, trapped light may propagate a considerable distance horizontally through the cover, substrate, or organic layers before being scattered out of the device, thereby reducing the sharpness of the device in pixellated applications such as displays.

U.S. Patent Application Publication No. 2004/0061136 entitled “Organic light emitting device having enhanced light extraction efficiency” by Tyan et al., describes an enhanced, light-extraction OLED device that includes a light-scattering layer. In certain embodiments, a low-index isolation layer (having an optical index substantially lower than that of the organic electroluminescent element) is employed adjacent to a reflective layer in combination with the light-scattering layer to prevent low-angle light from striking the reflective layer, and thereby minimize absorption losses due to multiple reflections from the reflective layer. The particular arrangements, however, may still result in reduced sharpness of the device.

EP1603367 A1 entitled “Electroluminescence Device” discloses an electroluminescent device successively comprising a cathode, an electroluminescent layer, a transparent electrode layer, an evanescent light-scattering layer comprising a matrix composed of a low-refractive material containing light-scattering particles, and a transparent sheet/plate. EP1603367 A1 also includes an internal low-refractive layer to inhibit the propagation of light in a cover or substrate.

Co-pending, commonly assigned U.S. Ser. No. 11/065,082, filed Feb. 24, 2005, the disclosure of which is incorporated by reference herein, describes the use of a transparent low-index layer having a refractive index lower than the refractive index of the encapsulating cover or substrate through which light is emitted and lower than the organic layers to enhance the sharpness of an OLED device having a scattering element. Both bottom-emitting and top-emitting embodiments are described. US 20050194896 describes a nano-structure layer for extracting radiated light from a light-emitting device together with a gap having a refractive index lower than an average refractive index of the emissive layer and nano-structure layer. Co-pending, commonly assigned U.S. Ser. No. 11/387,492, filed Mar. 23, 2006, the disclosure of which is incorporated by reference herein, describes processes for forming optical isolation layers having refractive index close to one in bottom-emitting devices, such as cavities filled with a gas, formed between a substrate and an EL element. However, the question of improving the lifetimes of OLED devices when formed in such top- and bottom-emitting structures themselves is not addressed. While transparent materials may be employed, because the layers 30, 32, and 34 are relatively thick in comparison to the light-emitting layer, light can travel some distance in these layers, possibly between light-emitting elements, and may thereby degrade the sharpness of the device. Moreover, the presence of light in the thin-film transistors 30 may change the transistors' operation and, although the transistors are relatively transparent, they may not be completely transparent or colorless, thereby changing the amount and color of light emitted, especially if employed in combination with a scattering layer, since application of scattering techniques may cause light to pass repeatedly through any layers between a reflector and the scattering layer.

There is a need therefore for an improved organic light-emitting diode device structure that avoids the problems noted above and improves the lifetime, efficiency, and sharpness of the device.

### SUMMARY OF THE INVENTION

In accordance with one embodiment, the invention is directed towards an organic light-emitting diode (OLED) device, comprising:

a transparent substrate;

one-or-more transparent thin-film transistors located over the substrate;

one or more light-emitting elements formed over the transparent thin-film transistors, wherein each light-emitting element comprises:
a first transparent extensive electrode formed at least partially over at least a portion of the one-or-more transparent thin-film transistors;
at least one layer of light-emitting organic material formed over the first transparent extensive electrode; and
a second reflective electrode formed over the at least one layer of light-emitting organic material;

a low-index layer formed between the first transparent extensive electrode and the one-or-more thin-film transistors, the low-index layer having a lower optical index than that of the layer of light-emitting organic material, the transparent thin-film transistors, and the transparent substrate; and

a light-scattering layer formed between the low-index layer and the second reflective electrode, or formed as part of the second reflective electrode.

### ADVANTAGES

The present invention has the advantage that it increases the lifetime, brightness, and sharpness of an OLED device.

### BRIEF DESCRIPTION OF THE DRAWINGS

FIG. 1 illustrates a cross section of a bottom-emitter OLED device having a scattering layer and low-index gap according to one embodiment of the present invention;

FIG. 2 illustrates a bottom-emitting OLED as suggested by the prior art;

FIG. 3 illustrates a cross section of a bottom-emitter OLED device having a scattering layer and a low-index gap according to an alternative embodiment of the present invention; and

FIG. 4 illustrates a cross section of a bottom-emitter OLED device having a scattering layer and a low-index gap according to a further embodiment of the present invention.

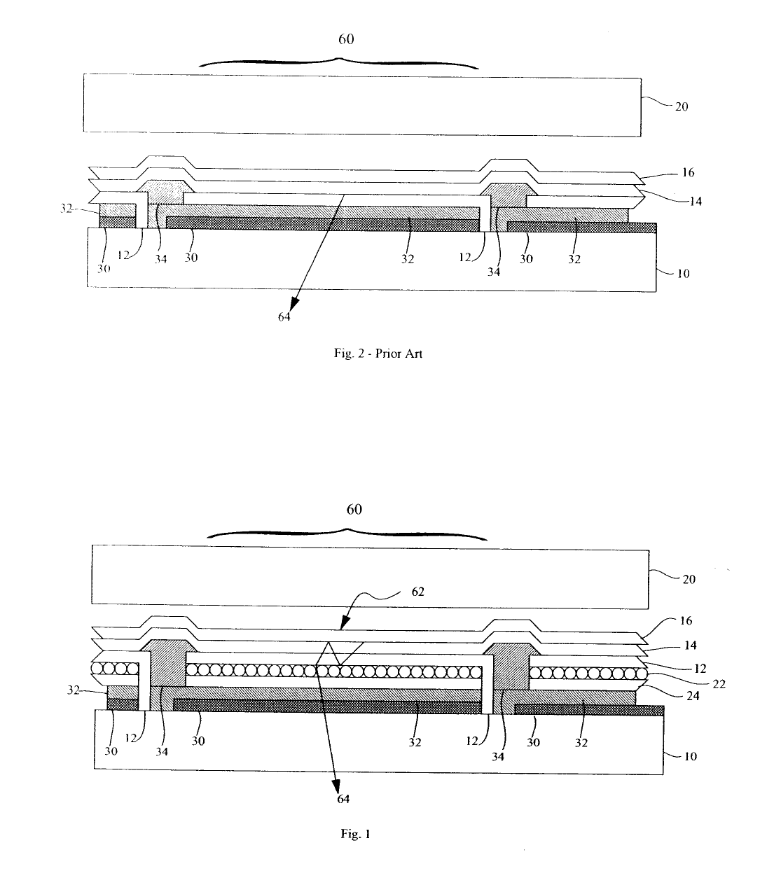

It will be understood that the figures are not to scale since the individual layers are too thin and the thickness differences of various layers too great to permit depiction to scale.

### DETAILED DESCRIPTION OF THE INVENTION

Referring to FIG. 1, in accordance with one embodiment of the present invention, an organic light-emitting diode (OLED) device, comprises a transparent substrate 10, one-or-more transparent thin-film transistors 30 located over the substrate 10; one or more light-emitting elements 62 formed over the transparent thin-film transistors 30, wherein each light-emitting element 62 comprises a first transparent extensive electrode 12 formed at least partially over at least a portion of the one-or-more transparent thin-film transistors 30, at least one layer 14 of light-emitting organic material formed over the first transparent extensive electrode, and a second reflective electrode 16 formed over the at least one layer 14 of light-emitting organic material; a low-index layer 24 formed between the first transparent extensive electrode 12 and the one-or-more thin-film transistors 30, the low-index layer 24 having a lower optical index than that of the layer 14 of light-emitting organic material, the transparent thin-film transistors 30, and the transparent substrate 10; and a light-scattering layer 22 formed between the low-index layer 24 and the second reflective electrode 16. In the particular embodiment of FIG. 1, the scattering layer 22 is formed between the low-index layer 24 and the first transparent extensive electrode 12. In alternative embodiments as discussed below, the scattering layer 22 may be formed as part of the second reflective electrode 16.

In operation an active-matrix OLED device such as that depicted in FIG. 1 employs transparent thin-film electronic components including transparent thin-film transistors 30 to provide a current through the patterned transparent extensive electrode 12, organic layer 14, and a reflective, unpatterned electrode 16. Planarization insulating layers 32 and insulating layers 34 protect the electronic components and prevent patterned transparent extensive electrodes 12 from shorting to each other and thereby form light-emissive areas 60. When a current is provided between the electrodes, one or more organic layers 14 emit light. The light is emitted in all directions so that some light will be emitted through the transparent extensive electrode 12, encounter the scattering layer 22, and be scattered into the low-index layer 24. Because the low-index layer 24 has a lower optical index than the transparent substrate 10 and transparent thin-film components 30, any light that enters the low-index layer 24 will also pass through the thin-film transistors 30 and transparent substrate 10. Light that is not scattered into the low-index layer 24 will eventually be reflected from the reflective electrode 16 and be re-scattered by the scattering layer 22 until the light eventually passes into the low-index layer 24 and exits the device through the substrate 10.

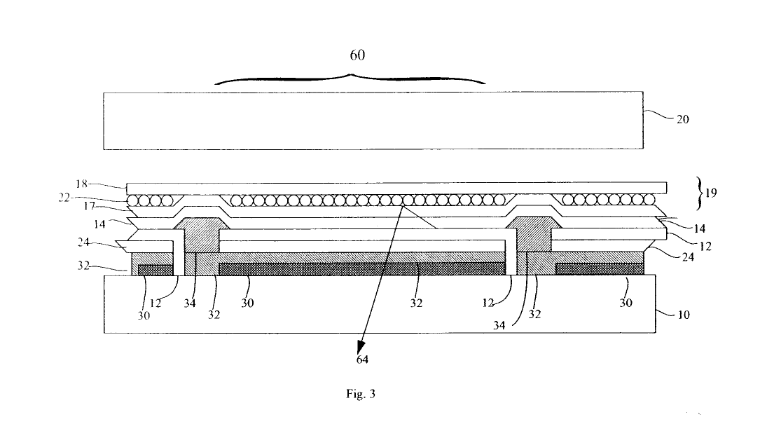

Referring to FIG. 3 in an alternative embodiment, a multi-layer reflective electrode 19 is formed over the organic layers 14. The multi-layer reflective electrode 19 comprises a transparent conductive layer 17, scattering layer 22, and a reflective layer 18. The transparent conductive layer 17 may comprise a conductive metal oxide, for example indium tin oxide or aluminum zinc oxide. The reflective layer 18 may also be conductive and comprise, for example, aluminum, silver, magnesium or various metallic alloys, and assist in the conduction of current to the transparent conductive layer 17. In this case, the scattering layer 22 may not be co-extensive with the transparent conductive layer 17 so that the reflective layer 18 may contact the transparent conductive layer 17. Preferably, such contacts are made between the light-emitting areas 60 of the OLED device and are defined by the patterning of the transparent extensive electrode 12. Scattering layer 22 itself may also comprise conductive elements. In a further embodiment, scattering layer 22 may comprise a rough light-scattering surface of a reflective electrode 16 or 19.

The scattering layer 22 may employ a variety of materials. For example, particles of SiNₓ (x>1), Si₃N₄, TiO₂, MgO, ZnO may be employed. Titanium dioxide (e.g., refractive index of 2.5 to 3) particles may be particularly preferred. Shapes of refractive particles may be variable or random, cylindrical, rectangular, or spherical, but it is understood that the shape is not limited thereto. Use of variable shaped particles is particularly preferred to enhance random scattering of light over wide wavelength and angle distributions. A large difference in refractive indices between materials in the scattering layer 22 and the low-index gap is generally desired, and may be, for example, from 0.3 to 3. It is generally preferred to avoid diffractive effects in the scattering layer. Such effects may be avoided, for example, by locating features randomly or by ensuring that the sizes or distribution of the refractive elements are not the same as the wavelength of the color of light emitted by the device from the light-emitting area. It is preferred that the total diffuse transmittance of the scattering layer coated on a glass support should be high (preferably greater than 80%) and the absorption of the scattering layer should be as low as possible (preferably less than 5%, and ideally 0%).

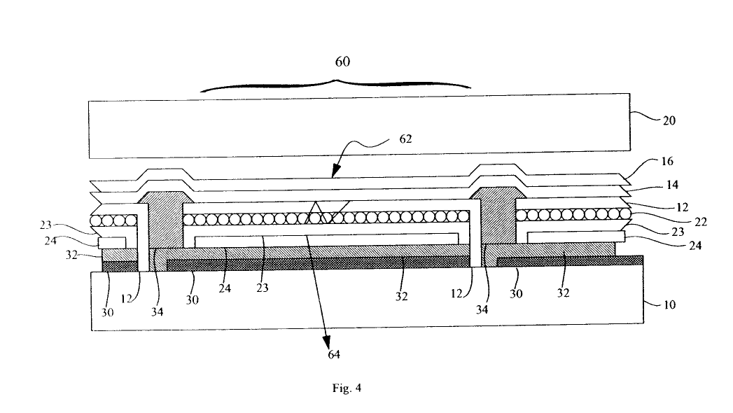

Low index layer 24 preferably comprises an optical isolation cavity such as may be formed as described in co-pending commonly assigned U.S. Ser. No. 11/387,492 incorporated by reference above. Such cavity may be filled with a gas, for example air or an inert gas such as nitrogen, argon or helium. This gas may be at reduced pressure compared to atmospheric pressure by forming under vacuum conditions. Preferably, the optical isolation cavity is at least one micron thick, and more preferably at least two microns thick. Such optical isolation cavity may be formed by depositing a sacrificial layer over for example, the insulating and planarizing layer 32. A second layer 23 (as shown in FIG. 4), or transparent electrode 12 itself, may then be formed over the sacrificial layer, the second layer 23 or electrode 12 having openings exposing portions of the sacrificial layer. An etchant may then be employed to etch the materials of the sacrificial layer away, leaving a cavity beneath the second layer 23 or electrode 12 forming the low-index layer 24 in the form of an optical isolation cavity. Further layers, for example the scattering layer 22 or transparent electrode 12 may be formed over the second layer 23. The second layer 23 or electrode 12 may be supported over the low-index layer 24 isolation cavity by walls adjacent to the light emitting areas 60 or by pillars of support material formed in the light-emissive area 60. The walls or pillars may comprise the same materials as the second layer 23 and be formed in a common patterning step. In such an embodiment, the sacrificial layer may be formed only in the light-emissive area 60.

Materials and etchants known in the photolithographic industry may be employed to form the sacrificial layer and/or second layer 23. In particular, the micro-electromechanical systems (MEMS) art describes useful techniques, as described in commonly assigned U.S. Pat. No. 6,238,581 entitled “Process for manufacturing an electromechanical grating device”. This disclosure describes a method for manufacturing a mechanical grating device comprising the steps of: providing a spacer layer on top of a protective layer which covers a substrate; etching a channel entirely through the spacer layer; depositing a sacrificial layer at least as thick as the spacer layer; rendering the deposited sacrificial layer optically coplanar by chemical mechanical polishing; providing a tensile ribbon layer completely covering the area of the channel; providing a conductive layer patterned in the form of a grating; transferring the conductive layer pattern to the ribbon layer and etching entirely through the ribbon layer; and removing entirely the sacrificial layer from the channel. With respect to the present invention, such a process can be simplified since the requirement for chemical mechanical polishing and the grating structure are unnecessary. Likewise, U.S. Pat. Nos. 6,307,663 and, in particular, 6,663,788 describe further devices having cavities and methods for forming cavities useful in the present invention. For example, the sacrificial layer may comprise a silicon, including a polysilicon or a silicon oxide, or an organic polymer, including a polyamide. The second layer may comprise a silicon nitride, a silicon oxide, or a metal oxide. The choice of materials will depend greatly on the choice of etchants, for example XeF₂ can etch silicon, such as polysilicon. Suitable cavities may be formed by employing a sacrificial layer of polysilicon formed over a silicon dioxide layer with a second layer of silicon nitride having photolithographically patterned openings exposing portions of the first sacrificial layer and then etching away the polysilicon sacrificial layer using XeF₂ gas. In an alternative embodiment, the sacrificial layer may be silicon dioxide covered with indium tin oxide (ITO) and hydrofluoric acid employed to etch out the silicon dioxide sacrificial layer. In this embodiment, the ITO layer may serve as a transparent electrode 12, thus eliminating the need for a separate second layer 23 and thereby may reduce materials costs, processing steps, and improve optical performance by avoiding light absorption in a separate second layer 23. Such an embodiment may be most useful in combination with the configuration of FIG. 3 that employs a scattering layer 22 adjacent to the reflective layer 18.

The present invention may be employed with both rigid (e.g. glass) or flexible (e.g. polymer) substrates. In preferred embodiments, the substrate 10 may comprise glass or plastic with typical refractive indices of between 1.4 and 1.6. Reflective second electrode 16 is preferably made of metal (for example aluminum, silver, or magnesium) or metal alloys. Transparent electrode 12 is preferably made of transparent conductive materials, for example indium tin oxide (ITO) or other metal oxides. The organic material layers 14 may comprise organic materials, for example, hole-injection, hole-transport, light-emitting, electron-injection, and/or electron-transport layers. Such organic material layers are well known in the OLED art. The organic material layers typically have a refractive index of between 1.6 and 1.9, while indium tin oxide has a refractive index of approximately 1.8-2.0. Hence, the various layers 12 and 14 in the OLED have a refractive index range of 1.6 to 2.1. Of course, the refractive indices of various materials may be dependent on the wavelength of light passing through them, so the refractive index values cited here for these materials are only approximate. In any case, the low-index layer 24 preferably has a refractive index at least 0.1 lower than that of the substrate, and thus will also typically have a refractive index lower than that of the organic layers. Most preferably, the low-index layer with comprise an optical isolation cavity and have a refractive index close to 1.

Transparent thin-film transistors that employ inorganic metal oxide semiconductors are known as discussed in the references cited above in the background of the Invention, and may comprise, e.g., zinc oxide, indium oxide, tin oxide, or cadmium oxide deposited with or without additional doping elements including transition metals such as aluminum. In a particular embodiment, the transparent thin-film transistors may be formed from zinc-oxide-based nano-particles as further discussed below. Such semiconductor materials may be transparent and are suitable for use with the present invention. However, as taught in the prior art, manufacturing processes for inorganic transparent thin-film transistors are typically incompatible with flexible substrates. Organic thin-film transistors, for example employing pentacene, are also known.

According to an embodiment of the present invention, a method of making an organic light-emitting diode (OLED) device, comprises the steps of: providing a transparent substrate; forming one-or-more transparent thin-film transistors located over the substrate; forming one or more light-emitting elements formed over the transparent thin-film transistors, wherein each light-emitting element comprises a first transparent extensive electrode formed at least partially over at least a portion of the one-or-more transparent thin-film transistors, at least one layer of light-emitting organic material formed over the first transparent extensive electrode, and a second reflective electrode formed over the at least one layer of light-emitting organic material; forming a low-index layer between the first transparent extensive electrode and the one-or-more thin-film transistors, the low-index layer having a lower optical index than that of the layer of light-emitting organic material; and forming a light-scattering layer between the low-index layer and the second reflective electrode, or formed as part of the second reflective electrode.

In particular embodiments of the present invention, methods for forming the transparent thin-film transistors may be employed that are compatible with the use of flexible substrates, in particular the use of low-heat processes.

### First Method

In a first embodiment of the present invention employing a low-temperature process for forming the transparent thin-film transistors, zinc-oxide-based nano-particles are employed as described in copending, commonly assigned U.S. Ser. No. 11/155,436, filed Jun. 16, 2005, the disclosure of which is incorporated herein by reference. In a preferred embodiment, the zinc-oxide-based semiconductor materials are “n-type,” although, through the use of suitable dopants, p-type materials are also envisioned. The zinc-oxide-based semiconductor material can contain other metals capable of forming semiconducting oxides such as indium, tin, or cadmium, and combinations thereof. Minor amounts of acceptor dopants can also be included.

The method of making a thin film comprising a zinc-oxide-based semiconductor comprises:

(a) applying, to a substrate, a seed coating comprising a colloidal solution of zinc-oxide-based nanoparticles having an average primary particle size of 5 to 200 nm;

(b) drying the seed coating to form a porous layer of zinc-oxide-based nanoparticles;

optionally annealing the porous layer of zinc-oxide-based nanoparticles at a temperature higher than the temperature of step (a) or (b);

(c) applying, over the porous layer of nanoparticles, an overcoat solution comprising a soluble zinc-oxide-precursor compound that converts to zinc oxide upon annealing, to form an intermediate composite film;

(d) drying the intermediate composite film; and

(e) annealing the dried intermediate composite film at a temperature of at least 50° C. to produce a semiconductor film comprising zinc-oxide-based nanoparticles supplemented by additional zinc oxide material formed by the conversion of the zinc-oxide-precursor compound during the annealing of the composite film.

In one embodiment of the present invention, the OLED device is constructed using a process for fabricating a thin film transistor, preferably by solution-phase deposition of the n-channel semiconductor film onto a substrate, preferably wherein the substrate temperature is at a temperature of no more than 300° C. during the deposition. In one embodiment, the nanoparticles are applied at room temperature followed by an annealing step carried out, typically, for one hour or less at a substrate temperature of 300° C. or less. Laser annealing may also be employed to allow the semiconductor to reach higher temperatures while maintaining relatively low substrate temperatures.

The invention is also directed to an OLED display employing a transistor comprising a zinc-oxide-based semiconductor, preferably on a flexible substrate, made by the present process.

Semiconductor films made by the present method are capable of exhibiting, in the film form, excellent field-effect electron mobility of greater than 0.01 cm²/Vs and on-off ratios of greater than 10⁴, in which performance properties are sufficient for use in a variety of relevant technologies, including active matrix display backplanes.

A TFT structure includes, in addition to the zinc-oxide-based semiconductor, conducting electrodes, commonly referred to as a source and a drain, for injecting a current into the zinc-oxide-based semiconductor. One embodiment of the present invention is directed to the use of such n-channel semiconductor films in thin film transistors each comprising spaced apart first and second contact means connected to an n-channel semiconductor film. A third contact means can be spaced from said semiconductor film by an insulator, and adapted for controlling, by means of a voltage applied to the third contact means, a current between the first and second contact means through said film. The first, second, and third contact means can correspond to a drain, source, and gate electrode in a field effect transistor.

Preferably, the seed coating is applied to the substrate at a level of 0.02 to 1 g/m² of nanoparticles, by dry-weight. The overcoat solution is preferably applied at a level of 2×10⁻⁴ to 0.01 moles/m² of precursor compound. In a preferred embodiment, the molar ratio of nanoparticles to theoretically converted zinc-oxide precursor compound is approximately 0.02 to 60, based on moles of ZnO and precursor compound present.

The seed coating and the overcoat can be applied by various methods, including conventional coating techniques for liquids. In one embodiment, the seed coating and/or the overcoat solution is applied using an inkjet printer. The inkjet printer can be a continuous or drop-on-demand inkjet printer. In a conventional inkjet printer, the method of inkjet printing a semiconductor film on a substrate element typically comprises: (a) providing an inkjet printer that is responsive to digital data signals; (b) loading a first printhead with the seed solution; (c) printing on the substrate using the seed solution in response to the digital data signals; (d) loading a second printhead with the overcoat solution (e) printing over the first coating using the overcoat solution in response to the digital data signals; and (f) annealing the printed substrate.

Other coating techniques include spin coating, extrusion coating, hopper coating, dip coating, or spray coating. In a commercial scale process, the semiconductor film can be coated on a web substrate which is later divided into individual semiconductor films. Alternately, an array of semiconductor films can be coated on a moving web.

For example, a layer of zinc-oxide-based nanoparticles may be applied by spin coating and subsequently annealed for about 10 seconds to 10 minute, preferably 1 minute to about 5 minutes in certain instances, at a temperature of about 50 to 500° C., preferably about 130 C to about 300° C., suitably in an ambient environment.

A semiconductor material, for use in an atmospheric process, must display several characteristics. In typical applications of a thin film transistor, the desire is for a switch that can control the flow of current through the device. As such, it is desired that when the switch is turned on a high current can flow through the device. The extent of current flow is related to the semiconductor charge carrier mobility. When the device is turned off, it is desired that the current flow be very small. This is related to the charge carrier concentration. Furthermore, it is desired that the device be weakly or not at all influenced by visible light. In order for this to be true, the semiconductor band gap must be sufficiently large (>3 eV) so that exposure to visible light does not cause an inter-band transition. A material that capable of yielding a high mobility, low carrier concentration, and high band gap is ZnO. Furthermore, in a real high-volume web-based atmospheric manufacturing scheme, it is highly desirable that the chemistries used in the process be both cheap and of low toxicity, which can be satisfied by the use of ZnO and the majority of its precursors.

As indicated above, the present method of making the zinc-oxide-based semiconductor thin film, for use in thin film transistors, employs nanoparticles of a zinc-oxide-based material. The zinc-oxide-based semiconductor material can contain minor amounts of other metals capable of forming semiconducting oxides such as indium, tin, or cadmium, and combinations thereof. For example, Chiang, H. Q. et al., “High mobility transparent thin-film transistors with amorphous zinc tin oxide channel layer,” Applied Physics Letters 86, 013503 (2005) discloses zinc tin oxide materials. Also, minor amounts of optional acceptor or donor dopants, preferably less than 10 weight percent, can also be included in the nanoparticles before or after deposition.

Accordingly, the term “zinc-oxide-based” refers to a composition comprising mostly zinc oxide, preferably at least 80 percent, but allowing additives or mixtures with minor amounts of other metal oxides, which semiconductor compositions are known to the skilled artisan.

Although undoped zinc-oxide-based nanoparticles can be employed in the present invention, the resistivity of the ZnO may be enhanced by substitutional doping with an acceptor dopant such as, for example, N, B, Cu, Li, Na, K, Rb, P, As, and mixtures thereof. Alternatively, p-type zinc-oxide films can be achieved, by the use of various p-type dopants and doping techniques. For example, U.S. Pat. No. 6,610,141 B2 to White et al. discloses zinc-oxide films containing a p-type dopant, for use in LEDs (light emitting devices), LDs (laser diodes), photodetectors, solar cells or other electrical devices where both n-type and p-type materials may be required for one or more multiple p-n junctions. White et al. employ diffusion of arsenic from a GaAs substrate to produce an arsenic-doped zinc-oxide-based film. U.S. Pat. No. 6,727,522 B1 also describes various dopants for p-type zinc-oxide-based semiconductor films, in addition to n-type dopants. Electrical devices in which zinc oxide is used as the n-type semiconductor and a different metal oxide, such as copper oxide or sodium cobalt oxide, is used as a p-type metal oxide are also known, as for example, described in EP 1324398 A2. Thus, the present invention can be used to make one or more semiconductor thin films in the same electrical device having a p-n junction, either by variously doped zinc-oxide-based semiconductor thin films made by the present method or by a zinc-oxide-based semiconductor thin film in combination with one or more other metal-oxide semiconductor thin films known in the art. For example, an electrical device made according to the present invention can include a p-n junction formed using a zinc-oxide-based thin film semiconductor made by the present method in combination with a thin film semiconductor of complementary carrier type as known in the art.

The thickness of the channel layer may vary, and according to particular examples it can range from about 5 nm to about 100 nm. The length and width of the channel is determined by the pixel size and the design rules of the system under construction. Typically, the channel width may vary from 10 to 1000 nm. The channel length may vary, and according to particular examples it can range from about 1 to about 100 μm.

The entire process of making the thin film transistor or electronic device, or at least the production of the thin film semiconductor, can be carried out below a support temperature of about 500° C., more preferably below 250° C., most preferably below about 150° C., and even more preferably below about 100° C., or even at temperatures around room temperature (about 25° C. to 70° C.). The temperature selection generally depends on the support and processing parameters known in the art, once one is armed with the knowledge of the present invention contained herein. These temperatures are well below traditional integrated circuit and semiconductor processing temperatures, which enables the use of any of a variety of relatively inexpensive supports, such as flexible polymeric supports. Thus, the invention enables production of relatively inexpensive circuits containing thin film transistors with significantly improved performance.

One embodiment of the present invention employs a process for fabricating a thin film transistor, preferably by solution-phase deposition of the semiconductor thin film onto a substrate, preferably wherein the substrate temperature is at a temperature of no more than 300° C. during the deposition. In such an embodiment, the nanoparticles are applied at room temperature followed by an annealing step carried out, typically, for one hour or less at a substrate temperature of 300° C. or less. Laser annealing may also be employed to allow the semiconductor to reach higher temperatures while maintaining relatively low substrate temperatures.

The nanoparticles used in embodiments of the present invention can be formed as a colloidal sol for application to the substrate. Preferably, nanoparticles having an average primary particles size of 5 to 200 nm, more preferably from 20 to 150 or from 20 to 100 nm, are colloidally stabilized in the coating solution, by charge, in the absence of surfactant. Charge stabilized sols are stabilized by repulsion between particles based on like surface charges. See C. Jeffrey Brinker and George W. Scherer, The Physics and Chemistry of Sol-Gel Processing, Academic Press (New York 1989).

Zinc-oxide-based nanoparticles can be formed from the reaction of an organometallic precursor such as zinc acetate that is hydrolyzed with a base such as potassium hydroxide. Other organometallic precursor compounds can include, for example, zinc acetylacetonate, zinc formate, zinc hydroxide, zinc chloride, zinc nitrate, their hydrates, and the like. Preferably, the organometallics precursor compound is a zinc salt of a carboxylic acid or a hydrate thereof, more preferably zinc acetate or a hydrate thereof. Optional doping materials can include, for example, aluminum nitrate, aluminum acetate, aluminum chloride, aluminum sulfate, aluminum formate, gallium nitrate, gallium acetate, gallium chloride, gallium formate, indium nitrate, indium acetate, indium chloride, indium sulfate, indium formate, boron nitrate, boron acetate, boron chloride, boron sulfate, boron formate, and their hydrates.

Preferably, after particle formation, the level of ions is reduced by washing to obtain a stable dispersion. Too many ions in solution can cause a screening of the particles from each other so that the particles approach too closely leading to aggregation and thus poor dispersion. Repeated washings allow the inorganic ion level to reach a preferred concentration of below 1 mM. Preferably, the level of organic compounds, or salts thereof, is maintained below a level of 5 mM.

In one embodiment, a substrate is provided and a layer of the semiconductor material as described above can be applied to the substrate, electrical contacts being made to the layer. The exact process sequence is determined by the structure of the desired semiconductor component. Thus, in the production of a field effect transistor, for example, a gate electrode can be first deposited on a flexible substrate, for example a vacuum or solution deposited metal or organic conductor. The gate electrode can then be insulated with a dielectric and then source and drain electrodes and a layer of the n-channel semiconductor material can be applied on top. The structure of such a transistor and hence the sequence of its production can be varied in the customary manner known to a person skilled in the art. Thus, alternatively, a gate electrode can be deposited first, followed by a gate dielectric, then the semiconductor can be applied, and finally the contacts for the source electrode and drain electrode deposited on the semiconductor layer. A third structure could have the source and drain electrodes deposited first, then the semiconductor, with dielectric and gate electrode deposited on top.

The skilled artisan will recognize other structures can be constructed and/or intermediate surface modifying layers can be interposed between the above-described components of the thin film transistor. In most embodiments, a field effect transistor comprises an insulating layer, a gate electrode, a semiconductor layer comprising a ZnO material as described herein, a source electrode, and a drain electrode, wherein the insulating layer, the gate electrode, the semiconductor layer, the source electrode, and the drain electrode are in any sequence as long as the gate electrode and the semiconductor layer contact opposite sides of the insulating layer, and the source electrode and the drain electrode both contact the semiconductor layer.

A thin film transistor (TFT) is an active device, which is the building block for electronic circuits that switch and amplify electronic signals. Attractive TFT device characteristics include a low voltage to turn it on, a high transconductance or (device current)/(gate) control-voltage ratio, and a high ‘on’ (Vg>0) current to ‘off’ (Vg≦0) current ratio. In one embodiment, the substrate may be a polymer, such as PET, PEN, KAPTON or the like. Source and drain conducting electrodes can be patterned on the substrate. The zinc-oxide-based semiconductor is then coated, followed by a gate-insulating layer such as SiO₂ or Al₂O₃ or a solution coated polymer. Finally, a gate-conducting electrode is deposited on the gate-insulating layer. One of skill in the art will recognize that this is one of many possible TFT fabrication schemes.

In the operation of such a TFT device, a voltage applied between the source and drain electrodes establishes a substantial current flow only when the control gate electrode is energized. That is, the flow of current between the source and drain electrodes is modulated or controlled by the bias voltage applied to the gate electrode. The relationship between material and device parameters of the zinc-oxide-based semiconductor TFT can be expressed by the approximate equation (see Sze in Semiconductor Devices—Physics and Technology, John Wiley & Sons (1981)):

$${I}_{d} = \frac{W}{2 L} μ {C ( {V}_{g} - {V}_{th} )}^{2}$$

where I_{d} is the saturation source-drain current, C is the geometric gate capacitance, associated with the insulating layer, W and L are physical device dimensions, μ is the carrier (hole or electron) mobility in the zinc-oxide-based semiconductor, and V_{g} is the applied gate voltage, and Vₜₕ is the threshold voltage. Ideally, the TFT allows passage of current only when a gate voltage of appropriate polarity is applied. However, with zero gate voltage, the “off” current between source and drain will depend on the intrinsic conductivity σ of the zinc-oxide-based semiconductor,

σ=nqμ

where n is the charge carrier density and q is the charge, so that

(I_{sd})=σ(Wt/L)V_{sd}@Vg=0

wherein t is the zinc-oxide-based semiconductor layer thickness and V_{sd} is the voltage applied between source and drain. Therefore, for the TFT to operate as a good electronic switch, e.g. in a display, with a high on/off current ratio, the semiconductor needs to have high carrier mobility but very small intrinsic conductivity, or equivalently, a low charge carrier density. On/off ratios >10⁴ are desirable for practical devices.

### Second Method

In an alternative embodiment of the present invention, the transparent thin-film transistors may be formed by chemical or atomic layer deposition (ALD), either in a vacuum, reduced pressure enclosure or in an atmospheric pressure enclosure, as described in copending, commonly assigned U.S. Ser. No. 11/392,007, filed Mar. 29, 2006, the disclosure of which is incorporated herein by reference. This process is an advantageous variation of ALD that allows for continuous exposure of a substrate to the gaseous materials used in the ALD reaction system while at the same time avoiding the use of a vacuum purge of each of the reactive gaseous materials after exposure to the substrate. Without wishing to be bound by theory, the transverse flow is believed to supply and remove gaseous materials from the surface of the substrate substantially by a diffusion process through a thin diffusion layer. The diffusion gradient is maintained, through the diffusion layer, by continuous flow of new gaseous material over the diffusion layer. The transverse flow can be provided by the use of elongated outlet channels openly positioned over the surface of the substrate.

In one method useful for the present invention, a process for thin-film material deposition onto a substrate comprises: simultaneously directing a series of gas flows along elongated channels such that the gas flows are substantially parallel to a surface of the substrate and substantially parallel to each other, whereby the gas flows are substantially prevented from flowing in the direction of the adjacent elongated channels, and wherein the series of gas flows comprises, in order, at least a first reactive gaseous material, inert purge gas, and a second reactive gaseous material, optionally repeated a plurality of times, wherein the first reactive gaseous material is capable of reacting with a substrate surface treated with the second reactive gaseous material.

In another method useful for the present invention, a process for thin-film material deposition onto a substrate comprises:

(a) providing a plurality of gaseous materials comprising at least first, second, and third gaseous materials, wherein the first and second gaseous materials are reactive with each other such that when one of the first or second gaseous materials are on the surface of the substrate the other of the first or second gaseous materials will react to deposit at least an atomic layer of material on the substrate and wherein the third gasesous material is inert with respect to reacting with the first or second gaseous materials;

(b) providing a substrate to be subjected to thin-film deposition of a material; and

(c) flowing the first, second and third gaseous materials into, respectively, into a plurality of elongated channels, each channel extending in a length direction substantially in parallel, the channels comprising at least a first, second, and third output channel for, respectively, the first, second and third gaseous material, wherein each of the channels substantially directs flow of the corresponding one of the first, second, or third gaseous materials along the length direction of the channel, substantially parallel to the substrate surface, preferably at a distance of under 1 mm from the substrate surface.

During the process, the substrate or distribution manifold for the gaseous materials, or both, is capable of providing relative movement between the output face of the distribution manifold and the substrate while maintaining the pre-designed close proximity.

In a preferred embodiment, the process can be operated with continuous movement of a substrate being subjected to thin film deposition, wherein the process is capable of conveying the support on or as a web past the distribution manifold, preferably in an unsealed environment to ambient at substantially atmospheric pressure.

The method provides a compact process for atomic layer deposition onto a substrate that is well suited to a number of different types of substrates and deposition environments. It also allows operation, in preferred embodiments, under atmospheric pressure conditions and is adaptable for deposition on a web or other moving substrate, including deposition onto a large area substrate. It is still a further advantage of the method employed for the present invention, that it can be employed in low-temperature processes at atmospheric pressures, which process may be practiced in an unsealed environment, open to ambient atmosphere.

The process employed offers a significant departure from conventional approaches to ALD, employing a compact distribution system for delivery of gaseous materials to a substrate surface, adaptable to deposition on larger and web-based substrates and capable of achieving a highly uniform thin-film deposition at improved throughput speeds. The process employs a continuous (as opposed to pulsed) gaseous material distribution. The process also allows operation at atmospheric or near-atmospheric pressures as well as under vacuum and is capable of operating in an unsealed or open-air environment.

In one embodiment, two reactive gases are used, a first molecular precursor and a second molecular precursor. Gases are supplied from a gas source and can be delivered to the substrate, for example, via a distribution manifold. Metering and valving apparatus for providing gaseous materials to a distribution manifold can be used. A continuous supply of gaseous materials for the system is provided for depositing a thin film of material on a substrate. With respect to a given area of the substrate (referred to as the channel area), a first molecular precursor or reactive gaseous material is directed to flow in a first channel transversely over the channel area of the substrate and reacts therewith. Relative movement of the substrate and the multi-channel flows in the system occurs, after which second channel (purge) flow with inert gas occurs over the given channel area. Then relative movement of the substrate and the multi-channel flows enables the given channel area to be subjected to atomic layer deposition in which a second molecular precursor now transversely flows (substantially parallel to the surface of the substrate) over the given channel area of the substrate and reacts with the previous layer on the substrate to produce (theoretically) a monolayer of a desired material. Often in such processes, a first molecular precursor is a metal-containing compound in gas form, and the material deposited is a metal-containing compound, for example, an organometallic compound such as diethylzinc. In such an embodiment, the second molecular precursor can be, for example, a non-metallic oxidizing compound.

Relative movement of the substrate and the multi-channel flows then enables the next step in which again an inert gas is used, this time to sweep excess second molecular precursor from the given channel area from the previous step. Then, relative movement of the substrate and the multi-channels occurs again, which sets the stage for a repeat sequence. The cycle is repeated as many times as is necessary to establish a desired film. In the present embodiment of the process, the steps are repeated with respect to a given channel area of the substrate, corresponding to the area covered by a flow channel. Meanwhile the various channels are being supplied with the necessary gaseous materials. Simultaneous with this sequence, other adjacent channel areas may be processed simultaneously, which results in multiple channel flows in parallel.

The primary purpose of the second molecular precursor is to condition the substrate surface back toward reactivity with the first molecular precursor. The second molecular precursor also provides material from the molecular gas to combine with metal at the surface, forming compounds such as an oxide, nitride, sulfide, etc, with the freshly deposited metal-containing precursor.

The method employed to construct the transparent thin-film transistors of the present invention is unique in that the continuous ALD purge does not need to use a vacuum purge to remove a molecular precursor after applying it to the substrate. Purge steps are expected by most researchers to be the most significant throughput-limiting step in ALD or chemical vapor deposition (CVD) processes.

Assuming that, for the two reactant gases, when the first reaction gas flow is supplied and flowed over a given substrate area, atoms of the first reaction gas are chemically adsorbed on a substrate, resulting in a layer and a ligand surface. Then, the remaining first reaction gas is purged with an inert gas. Then, the flow of the second reaction gas occurs and a chemical reaction proceeds between the adsorbed atoms and the second reaction gas, resulting in a molecular layer on the substrate. The remaining second reaction gas and by-products of the reaction are purged. The thickness of the thin film can be increased by repeating the process cycle many times.

Because the film can be deposited one monolayer at a time it tends to be conformal and have uniform thickness.

This process can been used to deposit a variety of materials useful for forming transparent thin-film transistors, including II-VI and III-V compound semiconductors, metals, and metal oxides and nitrides. Depending on the process, films can be amorphous, epitaxial or polycrystalline. Thus, in various embodiments of the present method a broad variety of process chemistries may be practiced, providing a broad variety of final films. Binary compounds of metal oxides that can be formed, for example, are tantalum pentoxide, aluminum oxide, titanium oxide, niobium pentoxide, zirconium oxide, hafnium oxide, zinc oxide, lanthium oxide, yttrium oxide, cerium oxide, vanadium oxide, molybdenum oxide, manganese oxide, tin oxide, indium oxide, tungsten oxide, silicon dioxide, and the like.

Thus, oxides that can be made using the present process include, but are not limited to: Al₂O₃, TiO₂, Ta₂O₅, Nb₂O₅, ZrO₂, HfO₂, SnO₂, ZnO, La₂O₃, Y₂O₃, CeO₂, Sc₂O₃, Er₂O₃, V₂O₅, SiO₂, and In₂O₃. Nitrides that can be made using the process of the present invention include, but are not limited to: AlN, TaNₓ, NbN, TiN, MoN, ZrN, HfN, and GaN. Fluorides that can be made using the process of the present invention include, but are not limited to: CaF₂, SrF₂, and ZnF₂. Metals that can be made using the process of the present invention include, but are not limited to: Pt, Ru, Ir, Pd, Cu, Fe, Co, and Ni. Carbides that can be made using the process of the present invention include, but are not limited to: TiC, NbC, and TaC. Mixed structure oxides that can be made using the process of the present invention include, but are not limited to: AlTiNₓ, AlTiOₓ, AlHfOₓ, AlSiOₓ, and HfSiOₓ. Sulfides that can be made using the process of the present invention include, but are not limited to: ZnS, SrS, CaS, and PbS. Nanolaminates that can be made using the process of the present invention include, but are not limited to: HfO₂/Ta₂O₅, TiO₂/Ta₂O₅, TiO₂/Al₂O₃, ZnS/Al₂O₃, ATO (AlTiO), and the like. Doped materials that can be made using the process of the present invention include, but are not limited to: ZnO:Al, ZnS:Mn, SrS:Ce, Al₂O₃:Er, ZrO₂:Y and the like.

It will be apparent to the skilled artisan that alloys of two, three or more metals may be deposited, compounds may be deposited with two, three or more constituents, and such things as graded films and nano-laminates may be produced as well. These variations are simply variants using particular embodiments of the method described in alternating cycles.

Various gaseous materials that may be reacted are also described in Handbook of Thin Film Process Technology, Vol. 1, edited by Glocker and Shah, Institute of Physics (IOP) Publishing, Philadelphia 1995, pages B1.5:1 to B1.5:16, hereby incorporated by reference; and Handbook of Thin Film Materials, edited by Nalwa, Vol. 1, pages 103 to 159, hereby incorporated by reference. In Table V1.5.1 of the former reference, reactants for various ALD processes are listed, including a first metal-containing precursors of Group II, III, IV, V, VI and others. In the latter reference, Table IV lists precursor combinations used in various ALD thin film processes.

Although oxide substrates provide groups for ALD deposition, plastic substrates can be used by suitable surface treatment.

While the discussion above describes the use of novel methods for forming transparent thin-film transistors for the OLED device of the present invention, these methods may also be employed for forming other active-matrix electronic components such as capacitors, resistive elements, and conductors. The use of transparent elements of these types provides increased transparency of the active-matrix area and improves light output from the device. However, some non-transparent components may be employed with the present invention. If the non-transparent components are reflective, emitted light that impinges on them may be reflected and re-scattered until the light is emitted. If they are absorptive, the light is lost, hence it is preferred that the relative amount of active-matrix components that are absorptive be minimized or that the light-emission area 60 be patterned so that light is not emitted above such light-absorptive areas. Such patterning may be done using careful layout and the processes described above. In a preferred embodiment of the present invention, photo-reactive materials are not employed in the light emissive areas.

The present invention may be employed in display devices. In a preferred embodiment, the present invention is employed in a flat-panel OLED device composed of small molecule or polymeric OLEDs as disclosed in but not limited to U.S. Pat. No. 4,769,292, issued Sep. 6, 1988 to Tang et al., and U.S. Pat. No. 5,061,569, issued Oct. 29, 1991 to VanSlyke et al. Many combinations and variations of organic light-emitting displays can be used to fabricate such a device, including both active- and passive-matrix OLED displays having either a top- or bottom-emitter architecture.

The invention has been described in detail with particular reference to certain preferred embodiments thereof, but it will be understood that variations and modifications can be effected within the spirit and scope of the invention.

### Parts List

10 transparent substrate
12 transparent electrode
14 organic layer(s)
16 reflective electrode
17 transparent conductive layer
18 reflective layer
19 multi-layer reflective electrode
20 cover
22 scattering layer
23 second layer
24 low-index layer
30 thin-film transistors
32 insulating planarization layer
34 insulating layer
60 emissive area
62 light-emitting element
64 light ray

1. An organic light-emitting diode (OLED) device, comprising:
a transparent substrate;
one-or-more transparent thin-film transistors located over the substrate;
one or more light-emitting elements formed over the transparent thin-film transistors, wherein each light-emitting element comprises:
a first transparent extensive electrode formed at least partially over at least a portion of the one-or-more transparent thin-film transistors;
at least one layer of light-emitting organic material formed over the first transparent extensive electrode; and
a second reflective electrode formed over the at least one layer of light-emitting organic material;
a low-index layer formed between the first transparent extensive electrode and the one-or-more thin-film transistors, the low-index layer having a lower optical index than that of the layer of light-emitting organic material, the transparent thin-film transistors, and the transparent substrate; and
a light-scattering layer formed between the low-index layer and the second reflective electrode, or formed as part of the second reflective electrode.

2. The OLED device of claim 1, wherein the scattering layer is formed between the low-index layer and the first transparent extensive electrode.

3. The OLED device of claim 1, wherein the second reflective electrode is a multi-layer electrode including a transparent layer and a reflective layer, the transparent layer being between the reflective layer and the one-or-more layer of organic material.

4. The OLED device of claim 3, wherein the scattering layer is formed between at least a portion of the transparent layer and a portion of the reflective layer.

5. The OLED device of claim 1, wherein the thin-film transistors are inorganic.

6. The OLED device of claim 1, wherein the thin-film transistors comprise metal oxide.

7. The OLED device of claim 6, wherein the metal oxide comprises zinc oxide, doped zinc oxide, or aluminum zinc oxide.

8. The OLED device of claim 1, wherein the thin-film transistors are organic.

9. The OLED device of claim 1, wherein the substrate is flexible.

10. The OLED device of claim 1, wherein the substrate comprises a polymer.

11. The OLED device of claim 1, wherein the transparent thin-film transistors are formed from zinc-oxide-based nano-particles.

12. The OLED device of claim 1, wherein the transparent thin-film transistors are formed by a method comprising the steps of:
(a) applying a seed coating comprising a colloidal solution of zinc-oxide-based nanoparticles having an average primary particle size of 5 to 200 nm to the transparent substrate;
(b) drying the seed coating to form a porous layer of zinc-oxide-based nanoparticles;
(c) applying, over the porous layer of nanoparticles, an overcoat solution comprising a soluble zinc-oxide-precursor compound that converts to zinc oxide upon annealing, to form an intermediate composite film;
(d) drying the intermediate composite film; and
(e) annealing the dried intermediate composite film at a temperature of at least 50° C. to produce a semiconductor film comprising zinc-oxide-based nanoparticles supplemented by additional zinc oxide material formed by the conversion of the zinc-oxide-precursor compound during the annealing of the composite film.

13. The OLED device of claim 12, further comprising annealing the porous layer of zinc-oxide-based nanoparticles at a temperature higher than the temperature of step (a) or (b) prior to applying the overcoat solution in step (c).

14. An OLED device of claim 12, wherein seed solution of step (a) and overcoat solution of step (c) are applied by ink-jet printing.

15. The OLED device of claim 1, wherein the transparent thin-film transistors are formed by simultaneously directing a series of gas flows along elongated channels such that the gas flows are substantially parallel to a surface of the substrate and substantially parallel to each other, whereby the gas flows are substantially prevented from flowing in the direction of the adjacent elongated channels, and wherein the series of gas flows comprises, in order, at least a first reactive gaseous material, inert purge gas, and a second reactive gaseous material, wherein the first reactive gaseous material is capable of reacting with a substrate surface treated with the second reactive gaseous material.

16. A method of making an organic light-emitting diode (OLED) device, comprising:
providing a transparent substrate;
forming one-or-more transparent thin-film transistors located over the substrate;
forming one or more light-emitting elements formed over the transparent thin-film transistors, wherein each light-emitting element comprises:
a first transparent extensive electrode formed at least partially over at least a portion of the one-or-more transparent thin-film transistors;
at least one layer of light-emitting organic material formed over the first transparent extensive electrode; and
a second reflective electrode formed over the at least one layer of light-emitting organic material;
forming a low-index layer between the first transparent extensive electrode and the one-or-more thin-film transistors, the low-index layer having a lower optical index than that of the layer of light-emitting organic material; and
forming a light-scattering layer between the low-index layer and the second reflective electrode, or formed as part of the second reflective electrode.
